(19) United States
(12) Patent Application Publication
(10) Pub. No.: US 2010/0033611 A1
(43) Pub. Date: Feb. 11, 2010

(54) Pixel array of three-dimensional image sensor

(75) Inventors: Seung-hoon Lee, Seoul (KR); Yoon-dong Park, Yongin-si (KR); Young-gu Jin, Hwaseong-si (KR); Seung-hyuk Chang, Seongnam-si (KR); Dae-kil Cha, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/461,063

(22) Filed: Jul. 30, 2009

(30) Foreign Application Priority Data
Aug. 6, 2008 (KR) 10-2008-0077022

(51) Int. Cl. H04N 13/02

(52) U.S. Cl. 348/302; 348/E13.074

(57) ABSTRACT

Provided is a pixel array of a three-dimensional image sensor. The pixel array includes unit pixel patterns each including a color pixel and a distance-measuring pixel arranged in an array form. The unit pixel patterns are arranged in such a way that a group of distance-measuring pixels are disposed adjacent to each other.

### FOREIGN PRIORITY STATEMENT

This application claims priority under 35 U.S.C. § 119 to Korean Patent Application No. 10-2008-0077022, filed on Aug. 6, 2008, in the Korean Intellectual Property Office (KIPO), the entire contents of which are incorporated herein by reference.

### BACKGROUND

1. Field

Example embodiments relates to a pixel array of a three-dimensional color image sensor, and more particularly, to a three-dimensional image sensor that measures a distance by selectively using each or combined signals of a plurality of distance-measuring pixels disposed adjacent to each other.

2. Description of the Related Art

A three-dimensional image sensor may realize colors of an object in three dimensions by measuring the color image of the object and the distance to the object. The three-dimensional image sensor may include color-measuring pixels and distance-measuring pixels. The color-measuring pixels (also referred to as color pixels below) may include red pixels, green pixels, blue pixels, etc, and the color pixels and the distance-measuring pixels may be arranged in an array form.

The size of a color pixel may be very small, for example, equal to or below 2 micrometers, and a conventional distance-measuring pixel may be larger than the color pixel. Accordingly, sizes of a micro lens for the color pixel and a micro lens for the distance-measuring pixel may be different. Additionally, a location of photoelectric conversion devices, for example, photodiodes for the color pixels in the substrate, may be different from that of the distance-measuring pixel. Consequently, it may be difficult to manufacture a three-dimensional image sensor due to sizes of the micro lenses and locations of the photodiodes.

Furthermore, a conventional three-dimensional image sensor may have low sensitivity according to illuminance.

### SUMMARY

Example embodiments provide a pixel array of a three-dimensional image sensor which may change a region of distance-measuring pixels according to illuminance.

Example embodiments also provide a three-dimensional image sensor, wherein sizes of micro lenses formed on a pixel array may be identical and locations of photoelectric converters may be identical.

Example embodiments provide of a three-dimensional image sensor comprising a plurality of unit pixel patterns, each unit pixel pattern comprising one or more color pixels and a distance-measuring pixel which are arranged in an array form, wherein the plurality of the unit pixel patterns are arranged in such a way that a group of the distance-measuring pixels are disposed adjacent to each other.

The group of the distance-measuring pixels disposed adjacent to each other may be four distance-measuring pixels, wherein the four distance-measuring pixels may be arranged in a square form.

The one or more color pixels may include at least two selected from the group consisting of a red pixel, a green pixel, a blue pixel, a magenta pixel, a cyan pixel, a yellow pixel, and a white pixel.

Each of the one or more color pixels and the distance-measuring pixel may substantially have the same size.

Example embodiments provide a pixel array of a three-dimensional image sensor, the pixel array including: a first color pixel pattern including N adjacent first color pixels; a second color pixel pattern including N adjacent second color pixels; a third color pixel pattern including N adjacent third color pixels; and a distance-measuring pixel pattern, wherein N is a natural number larger than 2.

The first through third color pixels may be selected from the group consisting of a red pixel, a green pixel, a blue pixel, a magenta pixel, a cyan pixel, a yellow pixel, or a white pixel.

The distance-measuring pixel pattern may include N adjacent distance-measuring pixels, wherein each of the first through third color pixels and the distance-measuring pixel may substantially have the same size.

The distance-measuring pixel may have an N-times larger size than each of the first through third color pixels.

Example embodiments provide a pixel array of a three-dimensional image sensor including: a color pixel pattern including a plurality of adjacent color pixels; and a distance-measuring pixel pattern having the substantially the same size as the color pixel pattern.

The distance-measuring pixel pattern may include a plurality of distance-measuring pixels.

The distance-measuring pixel pattern may include a distance-measuring pixel having substantially the same size as the color pixel pattern.

Example embodiments provide a three-dimensional image sensor including the pixel array; and a plurality of micro lenses, each of which is formed correspondingly to each of the one or more color pixels and the distance-measuring pixels, wherein the plurality micro lenses each have substantially same size.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a plan view schematically illustrating a pixel array of a three-dimensional image sensor, according to an example embodiment;

FIG. 2 is a cross-sectional view taken along line II-II of FIG. 1;

FIG. 3 is a plan view schematically illustrating a pixel array of a three-dimensional image sensor, according to another example embodiment;

FIG. 4 is a cross-sectional view taken along line IV-IV of FIG. 3;

FIG. 5 is a block diagram illustrating a configuration of a three-dimensional image sensor, according to an example embodiment;

FIG. 6 is an equivalent circuit diagram of a pixel of FIG. 5;

FIG. 7 is an equivalent circuit diagram of a distance-measuring pixel illustrated in FIGS. 1 and 3;

FIG. 8 is a block diagram illustrating a three-dimensional image sensor including a distance-measuring pixel of FIG. 7, according to example embodiments;

FIG. 9 is a block diagram illustrating a configuration of a three-dimensional image sensor, according to another example embodiment;

FIG. 10 is an equivalent circuit diagram of a pixel of FIG. 9;

FIG. 11 is an equivalent circuit diagram of a distance-measuring pixel of a three-dimensional image sensor, according to example embodiments;

FIG. 12 is a block diagram of FIG. 11;

FIG. 13 is a block diagram illustrating an image sensor, according to an example embodiment;

FIG. 14 is a block diagram illustrating an image sensor, according to another example embodiment;

FIG. 15 is a plan view schematically illustrating a pixel array of a three-dimensional image sensor, according to another example embodiment;

FIG. 16 is a cross-sectional view taken along line XVI-XVI of FIG. 15;

FIG. 17 is a plan view schematically illustrating a pixel array of a three-dimensional image sensor, according to another example embodiment;

FIG. 18 is a cross-sectional view taken along a line XVIII-XVIII of FIG. 17;

FIG. 19 is a plan view schematically illustrating a pixel array of a three-dimensional image sensor, according to another example embodiment; and

FIG. 20 is a cross-sectional view taken along line XX-XX of FIG. 19.

### DETAILED DESCRIPTION

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

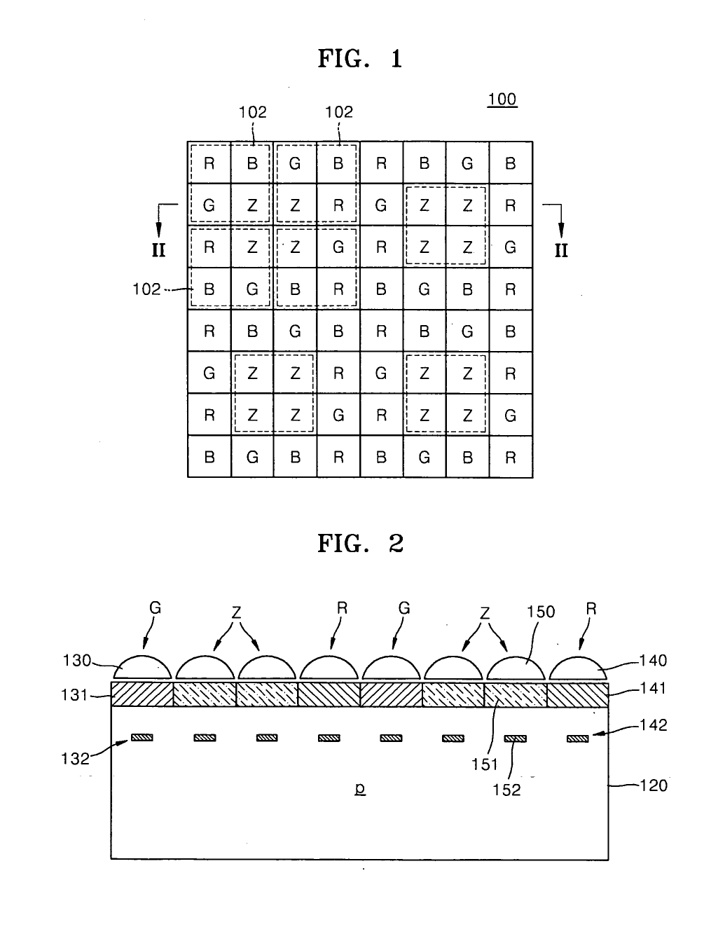

FIG. 1 is a plan view schematically illustrating a pixel array 100 of a three-dimensional image sensor, according to an example embodiment.

Referring to FIG. 1, the pixel array 100 of the three-dimensional image sensor may include red pixels R, green pixels G, and blue pixels B, which are color pixels, and distance measuring pixels Z. Four pixels consisting of the red, green, blue, and distance-measuring pixels, R, G, B, and Z, may be arranged to form a square. The red, green, blue, and distance measuring pixels R, G, B, and Z may have the same size.

Some of the distance-measuring pixels Z that are disposed adjacent to each other, for example, the four distance-measuring pixels Z of the four unit pixel patterns 102, may be arranged adjacent to each other to form a square shape. The distance-measuring pixel Z may measure the intensity of light having an infrared wavelength, and when the illuminance is low, the detection sensitivity of the distance-measuring pixel Z may become lower compared to that of the color pixel.

In FIG. 1, the color pixels illustrated in the pixel array 100 include the red pixels R, the green pixels G, and the blue pixels B, but example embodiments are not limited thereto. For example, the color pixels may include at least two pixels among a red pixel R, a green pixel G, a blue pixel B, a magenta pixel Mg, a cyan pixel Cy, a yellow pixel Y, and a white pixel W.

FIG. 2 is a cross-sectional view taken along line II-II of FIG. 1. Referring to FIG. 2, the green, red, and distance-measuring pixels G, R, and Z may be formed on a substrate 120, for example, on a p-type silicon substrate. The green pixel G may include a micro lens 130, a green filter 131, and a photoelectric conversion device 132. The red pixel R may include a micro lens 140, a red filter 141, and a photoelectric conversion device 142. The photoelectric conversion devices 132 and 142 may be n-type regions, and may form a p-n junction photodiode with the p-type substrate 120.

The distance-measuring pixel Z may include a micro lens 150, an infrared filter 151, and a photoelectric conversion device 152. The photoelectric conversion device 152 may be an n-type region, and may form a p-n junction photodiode with the p-type substrate 120.

The photoelectric conversion devices 132, 142, and 152 may be referred to as photodiodes. Additionally, a color filter may indicate not only a red filter, a green filter, and a blue filter, but also an infrared filter.

The micro lenses 130, 140, and 150 may have substantially the same size. The photoelectric conversion devices 132, 142, and 152 may receive a focused light from the micro lenses 130, 140, and 150, and since the micro lenses 130, 140, and 150 may have substantially the same size, the photoelectric conversion devices 132, 142, and 152 may be located at the same depth from the surface of the substrate 120. Additionally, although not illustrated in FIG. 2, the blue pixel B may have the same structure as the green pixel G, the red pixel R, and the distance-measuring pixel Z.

Accordingly, the photoelectric conversion devices 132, 142, and 152 may be formed at the same depth from the substrate 120, and the micro lenses 130, 140, and 150, which may have the same size, may be formed via etching by using a conventional semiconductor process, and thus the three-dimensional image sensor according to example embodiment may be easily manufactured.

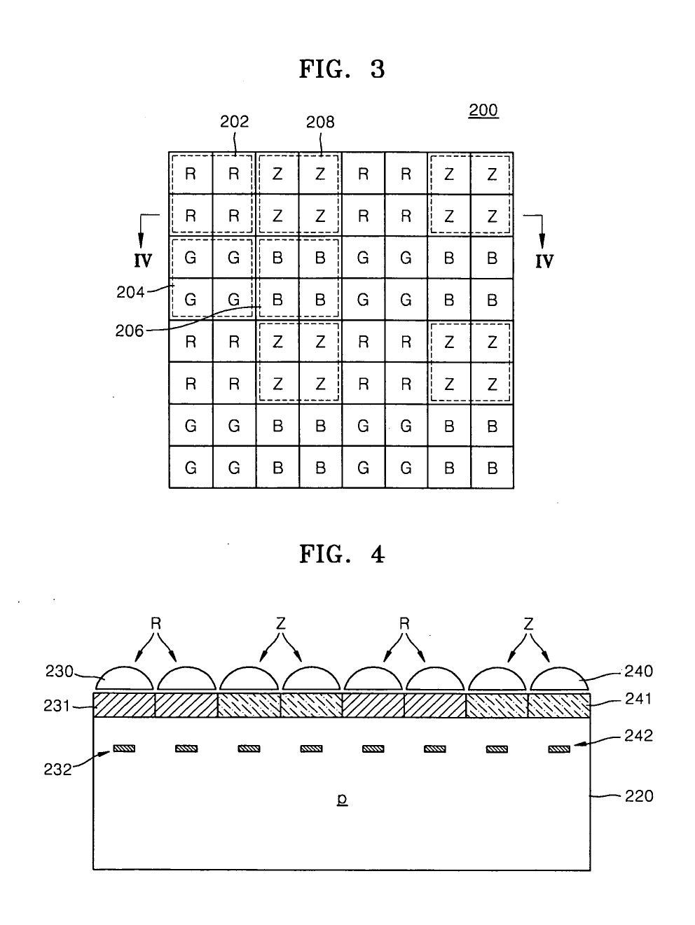

FIG. 3 is a plan view schematically illustrating a pixel array 200 of a three-dimensional image sensor, according to anther example embodiment.

Referring to FIG. 3, the pixel array 200 may include color pixel patterns including a red pixel pattern 202, a green pixel pattern 204, and a blue pixel pattern 206, and a distance-measuring pixel pattern 208. Each of the red pixel, green pixel, blue pixel, and the distance-measuring pixel patterns 202, 204, 206, and 208 may have substantially the same size.

In FIG. 3, the red pixel pattern 202, the green pixel pattern 204, and the blue pixel pattern 206 are, respectively, illustrated as including 4 red pixels R, 4 green pixels G, and 4 blue pixels B. In FIG. 3, though each color pixel pattern is illustrated as including 4 color pixels, example embodiments are not limited thereto. For example, each color pixel pattern may include 2 or 3 color pixels.

In FIG. 3, the color pixel patterns are illustrated as including the red pixels R, the green pixels G, and the blue pixels B, but example embodiments are not limited thereto. For example, the color pixel patterns may include at least 3 pixels from among the red pixels R, the green pixels G, the blue pixels B, magenta pixels Mg, cyan pixels Cy, yellow pixels Y, and white pixels W.

The distance-measuring pixel pattern 208 may include a plurality of, for example, four, distance-measuring pixels Z. The four distance-measuring pixels Z may be disposed adjacent to each other. The distance-measuring pixel Z may measure the intensity of light having an infrared wavelength, and may have low light detection sensitivity when illuminance is low compared to other lights having wavelengths of other color pixels.

A plurality of each of the color pixels, for example, four of each color pixel, may be disposed adjacent to each other to form a square.

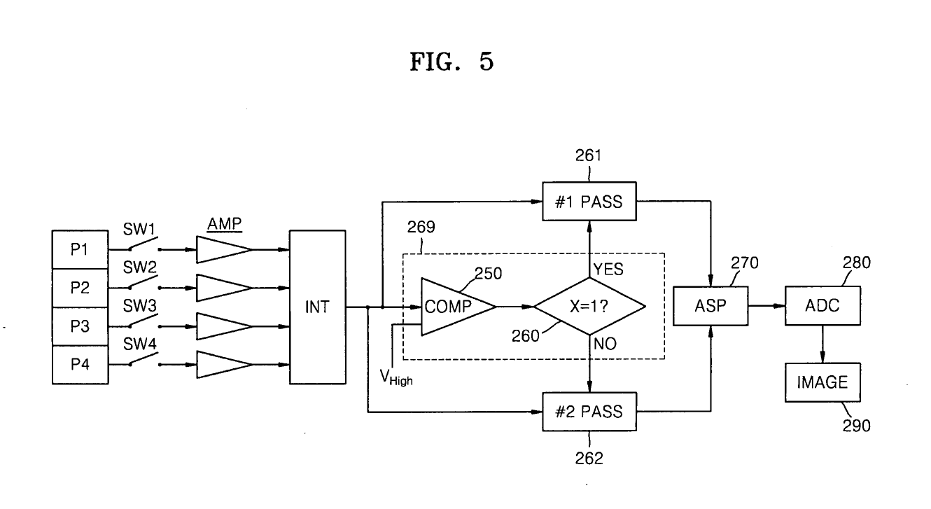

FIG. 4 is a cross-sectional view taken along line IV-IV of FIG. 3. Referring to FIG. 4, the red pixel R and the distance-measuring pixel Z may be formed on a substrate 220, for example a p-type silicon substrate. The red pixel R may includes a micro lens 230, a red filter 241, and a photoelectric conversion device 232. The photoelectric conversion device 232 may be an n-region, and may form a p-n junction photodiode with the p-type substrate 220.

The distance-measuring pixel Z may include a micro lens 240, an infrared filter 241, and a photoelectric conversion device 242. The photoelectric conversion device 242 may be an n-type region, and may form a p-n junction photodiode with the p-type substrate 220. The photoelectric conversion devices 232 and 242 may be referred to as photodiodes. Additionally, a color filter may indicate not only a red filter, a green filter, and a blue filter, but also an infrared filter.

The micro lenses 230 and 240 may have substantially the same size. The photoelectric conversion devices 232 and 242 may receive a focused light from the micro lenses 230 and 240, and since the micro lenses 230 and 240 may have substantially the same size, the photoelectric conversion devices 232 and 242 may be located at the same depth from the surface of the substrate 220. Additionally, although not illustrated in FIG. 3, the green and blue pixels G and B may have substantially the same structure as the red pixel R and the distance-measuring pixel Z.

Accordingly, the photoelectric conversion devices 232 and 242 may be formed at the same depth from the substrate 220, and the micro lenses 230 and 240, which may have the same size, may be formed via etching by using a conventional semiconductor process. Accordingly, the three-dimensional image sensor according to example embodiments may be easily manufactured.

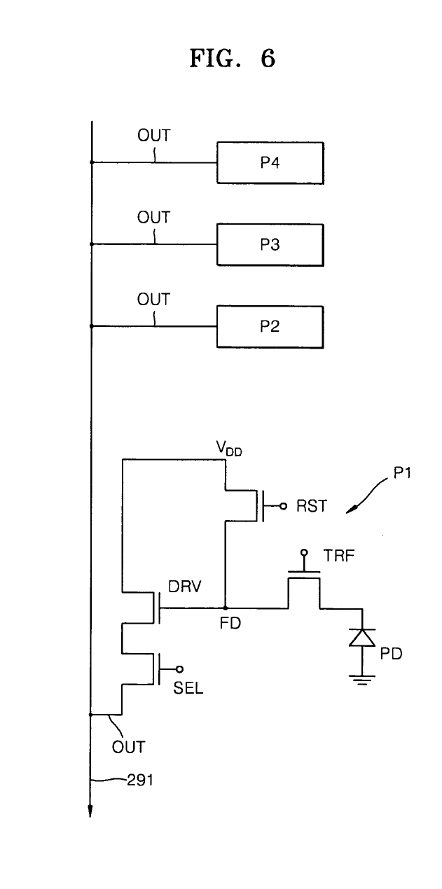

FIG. 5 is a block diagram illustrating a configuration of a three-dimensional image sensor, according to an example embodiment.

Referring to FIG. 5, four same color pixels P1 through P4, which may be disposed adjacent to each other as shown in FIG. 4, may have four amplifiers AMPs connected to each of the color pixels P1 through P4, and an integrator INT, to which electric signals from the 4 amplifiers AMPs may be inputted. Four switching units SW1 through SW4 may be respectively disposed between the color pixels P1 through P4 and the 4 amplifiers AMPs.

The color pixels P1 through P4 may be one of a red pixel R, a green pixel G, a blue pixel B, a magenta pixel Mg, a cyan pixel Cy, a yellow pixel Y, or a white pixel W.

When the switching units SW1 through SW4 are all turned on, signals from the color pixels P1 through P4 may be integrated in the integrator INT, and a signal from the integrator INT may be transmitted to a comparator 250 and a determiner 260. The comparator 250 may compare a value of the received signal with a reference value V_{High}, and when the value of the received signal is equal to or below the reference value V_{High}, the comparator 250 may transmit a signal “1” to the determiner 260. When the value of the received signal is above the reference value V_{High}, the comparator 250 may transmit a signal “0” to the determiner 260. Then, when the signal “1” is received, the determiner 260 may open a first pass gate 261, and when the signal “0” is received, the determiner 260 may open a second pass gate 262. An analog signal integrated in the integrator INT may be transmitted to the first pass gate 261, and this analog signal is may be transmitted to an analog signal processor 270.

When the second pass gate 262 is opened, the switching units SW1 through SW4 may be sequentially opened and closed, and thus the electric signals from the color pixels P1 through P4 may be sequentially transmitted to the integrator INT. Then, the electric signals from the integrator INT may be sequentially transmitted to the analog signal processor 270.

The comparator 250 and the determiner 260 may form a signal controller 269 that selects a signal to be transmitted to the analog signal processor 270 according to the illuminance.

The signal transmitted to the analog signal processor 270 may be inputted to an analog-digital converter 280, converted to a digital signal in the analog-digital converter 280, and then transmitted to an image signal processor 290.

FIG. 6 is an equivalent circuit diagram of the color pixels P1 through P4 of FIG. 5.

Referring to FIG. 6, each of the color pixels P1 through P4 may include a transfer transistor TRF, a reset transistor RST, a drive transistor DRV, and a select transistor SEL. Output lines OUT, which may each be connected to one end of the select transistors SEL of the color pixels P1 through P4, may be connected to an integrated output line 291 in parallel.

A floating diffusion region FD may be connected to a gate of the drive transistor DRV and to the reset transistor RST, and the drive transistor DRV may transmit a signal from the floating diffusion region FD to the integrated output line 191 via the select transistor SEL.

The switching units SW1 through SW4 of FIG. 5 may respectively be the select transistors SEL. Additionally, the switching units SW1 through SW4 may be switches (not shown) respectively disposed between the select transistors SEL and the integrated output line 291.

The integrator INT of FIG. 5 may be the integrated output line 291, and in order to integrate all signals from the color pixels P1 through P4, the switching units SW1 through SW4 may be simultaneously turned on. Additionally, the switching units SW1 through SW4 may be sequentially turned on so as to obtain each signal from the color pixels P1 through P4.

Each amplifier AMP of FIG. 5 may be constituted of the drive transistor DRV and the select transistor SEL of a corresponding pixel.

According to the structure of FIGS. 5 and 6, only one signal may be transmitted to the analog signal processor 270, and thus the number of required analog digital converter 280 may be reduced.

According to the three-dimensional image sensor 200, when the illuminance is low, one pixel data may be acquired by detecting sum of light irradiated on a region of four pixels so as to use as each pixel data of the four pixels, and thus sensitivity of the three dimensional image sensor 200 may be improved. Additionally, when the illuminance is high, each pixel data may be independently used as image data, and thus the image resolution may be improved.

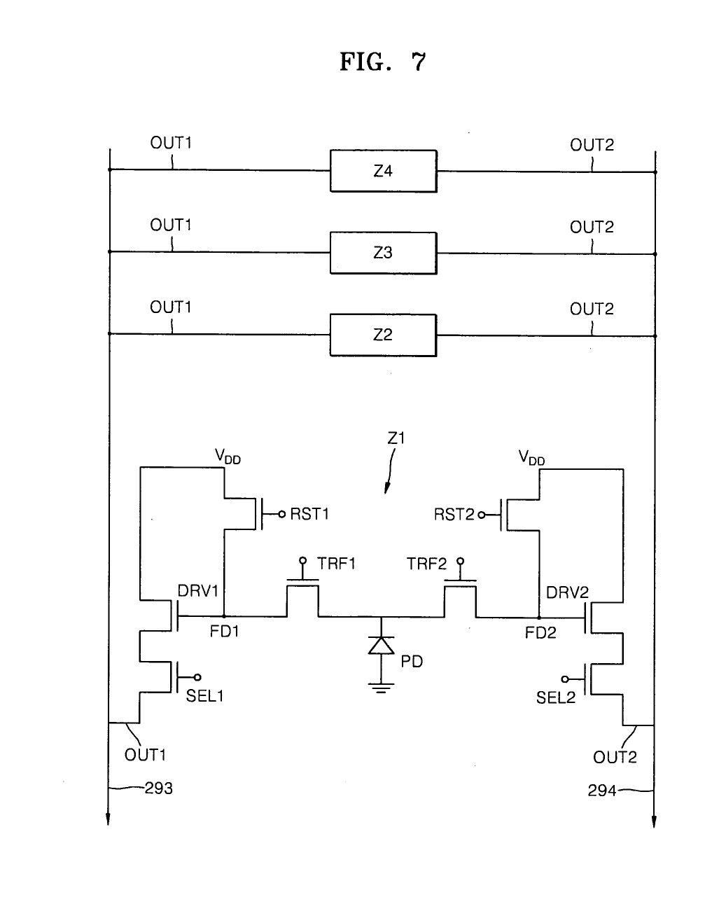

FIG. 7 is an equivalent circuit diagram of distance-measuring pixels illustrated in FIGS. 1 through 3. Like reference numerals in the drawings denote like elements as in above embodiments, and details thereof are not repeated.

Referring to FIG. 7, each of 4 distance-measuring pixels Z1 through Z4 that are disposed adjacent to each other may include one photodiode PD, and first and second circuits to which charges from the photodiode PD having phase differences may be transferred. The first circuit may include a transfer transistor TRF1, a reset transistor RST1, a drive transistor DRV1, and a select transistor SEL1. The second circuit may include a transfer transistor TRF2, a reset transistor RST2, a drive transistor DRV2, and a select transistor SEL2. Output lines OUT1 of the first circuits of the distance measuring pixels Z1 through Z4 may be connected to a first integrated output line 293 in parallel, and output lines OUT2 of the second circuits may be connected to a second integrated output line 294 in parallel. In FIG. 7, some configurations of the distance-measuring pixels Z2 through Z4 are omitted.

The first or second integrated output line, 293 or 294, may be used to measure illuminance of an object, and whether to integrate signals from the distance-measuring pixels Z1 through Z4 or to separately use signals from the distance-measuring pixels Z1 through Z4 may be determined based on the illuminance of the object.

A first floating diffusion region FD1 may be connected to a gate of the first drive transistor DRV1 and the reset transistor RST1, and a second floating diffusion region FD2 may be connected to a gate of the drive transistor DRV2 and the reset transistor RST2. The drive transistors DRV1 and DRV2 transmit signals from the first and second floating diffusion regions FD1 and FD2, respectively, to the first and the second integrated output lines 293 and 294 via the select transistors SEL1 and SEL2.

Meanwhile, photo gates (not shown) may further be formed between the photodiode and the transfer transistors TRF1 and TRF2.

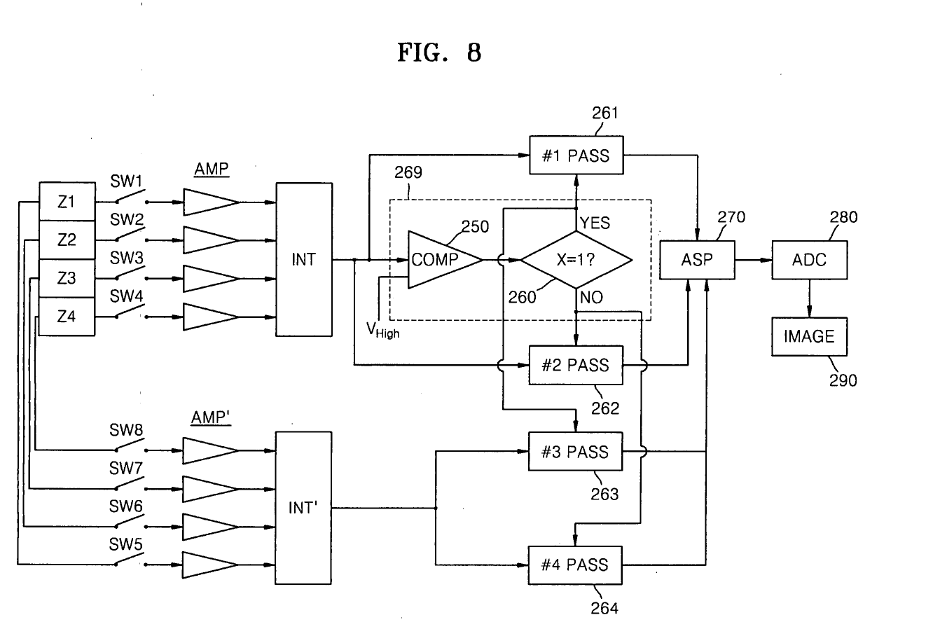

FIG. 8 is a block diagram illustrating a three-dimensional image sensor including the distance-measuring pixels Z1 through Z4 of FIG. 7. Like reference numerals in the drawings denote like elements, and details thereof will not be repeated.

Referring to FIG. 8, in comparison to the structure of the color pixels shown in FIG. 5, the distance-measuring pixels Z1 through Z4 may further include switching units SW5 through SW8, amplifiers AMP′, each of which may be connected to the switching units SW5 through SW8, and an integrator INT′, to which signals from the amplifiers AMP′ may be inputted. A signal from the integrator INT′ may be transmitted to a third pass gate 263 and a fourth pass gate 264, and signals from the third and fourth pass gates 263 and 264 may be transmitted to the analog signal processor 270, the analog digital converter 280, and the image signal processor 290.

The switching units SW1 through SW4 of FIG. 8 may be the select transistors SEL1 of the distance-measuring pixels Z1 through Z4, respectively, and the switching units SW5 through SW8 may be the select transistors SEL2 of the distance measuring pixels Z1 through Z4, respectively. Alternatively, the switching units SW1 through SW8 may be switches (not shown) disposed between the select transistors SEL1 and SEL2 and the first and second integrated output lines 293 and 294, respectively.

The integrators INT and INT′ of FIG. 8 may be the first and second integrated output lines 293 and 294, respectively. The amplifiers AMP and AMP′ of FIG. 8 may be constituted of the drive transistors DRV1 and DRV2 and the select transistors SEL1 and SEL2 of a corresponding pixel.

When the switching units SW1 through SW4 are all turned on, signals from the pixels Z1 through Z4 may be integrated in the integrator INT, and a signal from the integrator INT may be transmitted to the comparator 250 and the determiner 260. The comparator 250 may compare a value of the received signal with a reference value V_{High}, and when the value is equal to or below the reference value V_{High}, the comparator 250 may transmit a signal “1” to the determiner 260, and when the value is above the reference value V_{High}, the comparator 250 may transmits a signal “0” to the determiner 260. When the signal “1” is received, the determiner 260 may open the first and third pass gates 261 and 263, and when the signal “0” is received, the determiner 260 may open the second and fourth pass gates 262 and 264.

The comparator 250 and the determiner 260 may form a signal controller 269, and the signal controller 269 may select a signal to be transmitted to the analog signal processor 270 according to the intensity of illuminance.

When the signal “1” is received, i.e., when the intensity of light from the object is low, an analog signal integrated in the integrator INT may be transmitted to the first pass gate 261, and the analog signal at the first pass gate 261 may be transmitted to the analog signal processor 270. An analog signal integrated in the integrator INT′ may be transmitted to the third pass gate 263, and the analog signal at the third pass gate 263 may be transmitted to the analog signal processor 270. The switching units SW1 through SW4 may be turned on together and the switching units SW5 through SW8 may be turned on together in a phase difference with the switching units SW1 through SW4, and accordingly, signals from the distance-measuring pixels Z1 through Z4 may be sequentially transmitted to the analog signal processor 270 as two signals having a phase difference.

When the signal “0” is received, i.e., when the intensity of light from the object is high, the second and fourth pass gates 262 and 264 may be opened, and switching units SW1 through SW4 may be sequentially opened and shut. Accordingly, electric signals from the distance-measuring pixels Z1 through Z4 may be sequentially transmitted to the integrator INT, and the electric signals may be sequentially transmitted to the analog signal processor 270. Additionally, the switching units SW5 through SW8 may be sequentially opened and shut to have phase differences with corresponding switching units SW1 through SW4. Accordingly, electric signals from the distance-measuring pixels Z1 through Z4 may be sequentially transmitted to the integrator INT′. Signals having phase differences from the integrators INT and INT′ may be sequentially transmitted to the analog signal processor 270.

The signals transmitted to the analog signal processor 270 may be converted to digital signals in the analog-to-digital converter 280, and then transmitted to the image signal processor 290.

Measuring a distance from the subject by using the signals having a phase difference is well known to those of ordinary skill in the art, and thus details thereof are omitted herein.

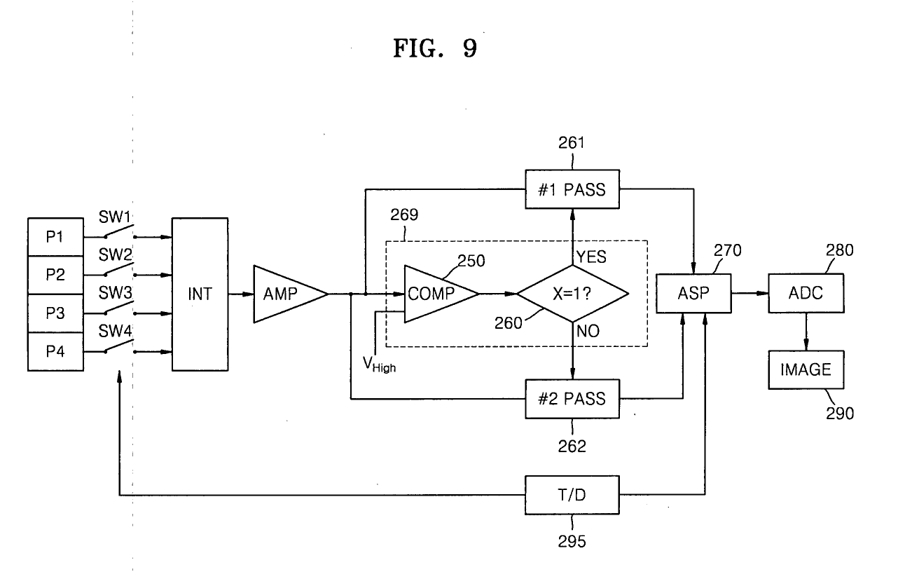

FIG. 9 is a block diagram illustrating a configuration of a three-dimensional image sensor, according to another example embodiment.

Referring to FIG. 9, four adjacent color pixels P1 through P4 may have the switching units SW1 through SW4 respectively connected to the color pixels P1 through P4, the integrator INT that may be connected to the switching units SW1 through SW4 to receive signals from the color pixels P1 through P4, and the amplifier AMP to which a signal from the integrator INT may be received.

The color pixels P1 through P4 may each be one of red pixels R, green pixels G, blue pixels B, magenta pixels Mg, cyan pixels Cy, yellow pixels Y, or white pixels W.

When the switching units SW1 through SW4 are all turned on, the signal from the integrator INT may be transmitted to the comparator 250 and the determiner 260. The comparator 250 may compare a value of the received signal with a reference value V_{High}, and when the value of the received signal is equal to or below the reference value V_{High}, the comparator 250 may transmit a signal “1” to the determiner 260, and when the value of the received signal is above the reference value V_{High}, the comparator 250 may transmit a signal “0” to the determiner 260. Accordingly, when the signal “1” is received, the determiner 260 may open the first pass gate 261, and when the signal “0” is received, the determiner 260 may open the second pass gate 262. An analog signal integrated in the integrator INT may be transmitted to the first pass gate 261, and this analog signal may be transmitted to the analog signal processor 270.

When the second pass gate 262 is opened, a time divider 295 may sequentially open and close the switching units SW1 through SW4, and thus electric signals from the color pixels P1 through P4 may be sequentially transmitted to the integrator INT. Accordingly, the electric signals may be sequentially transmitted to the analog signal processor 270 via the second pass gate 262. The time divider 295 may transmits a synchronization signal to the analog signal processor 270. The synchronization signal may include information about pixels P1 through P4 from which each signal is transmitted to the analog signal processor 270. The comparator 250 and the determiner 260 form a signal controller 269, and the signal controller 269 may select a signal to be transmitted to the analog signal processor 270 according to the intensity of illuminance.

The signal transmitted to the analog signal processor 270 may be converted to a digital signal in the analog-to-digital converter 280, and then transmitted to the image signal processor 290.

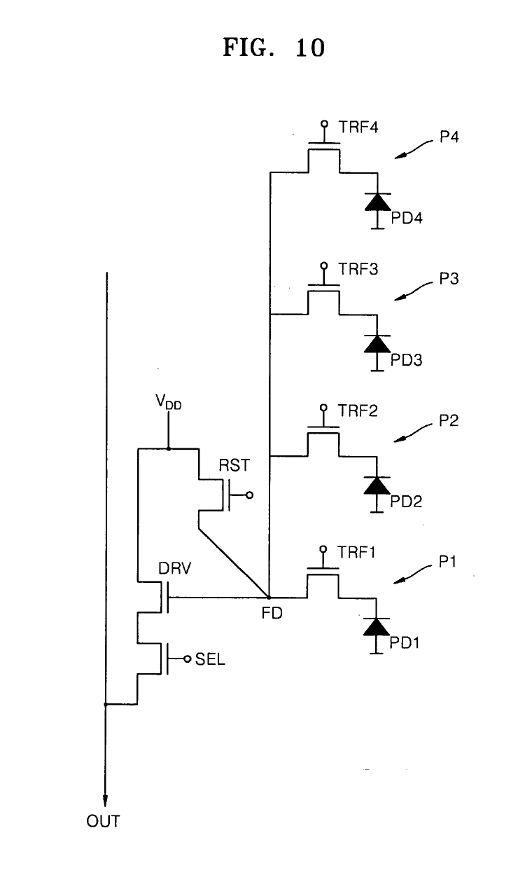

FIG. 10 is an equivalent circuit diagram of the color pixels P1 through P4 of FIG. 9.

Referring to FIG. 10, the color pixels P1 through P4 may include photodiodes PD1 through PD4 and transfer transistors TRF1 through TRF4, respectively. First ends of the transfer transistors TRF1 through TRF4 may be respectively connected to the photodiodes PD1 through PD4, and second ends of the transfer transistors TRF1 through TRF4 may be connected to a floating diffusion region FD in parallel.

The color pixels P1 through P4 may further include a reset transistor RST connected to the floating diffusion region FD, a drive transistor DRV having a gate connected to the floating diffusion region FD, and a select transistor SEL.

The drive transistor DRV and the select transistor SEL may form an amplifier AMP in FIG. 9. The switching units SW1 through SW4 of FIG. 9 may be the transfer transistors TRF1 through TRF4, respectively. Alternatively, the switching units SW1 through SW4 may be switches (not shown) formed between the transfer transistors TRF1 through TRF4 and the floating diffusion region FD, respectively.

The integrator INT of FIG. 9 may be the floating diffusion region FD of FIG. 10, and the switching units SW1 through SW4 may be simultaneously turned on in order to integrate all the signals from the color pixels P1 through P4. Additionally, in order to separately obtain signals from the color pixels P1 through P4, the switching units SW1 through SW4 may be sequentially turned on by using the time divider 295.

According to the embodiment of FIGS. 9 and 10, the number of signals inputted to the analog signal processor 270 may be one, and thus the number of analog digital converter 280 may be reduced. Additionally, since the number of amplifiers AMP required by the color pixels P1 through P4 may be one, the number of transistors may be remarkably reduced.

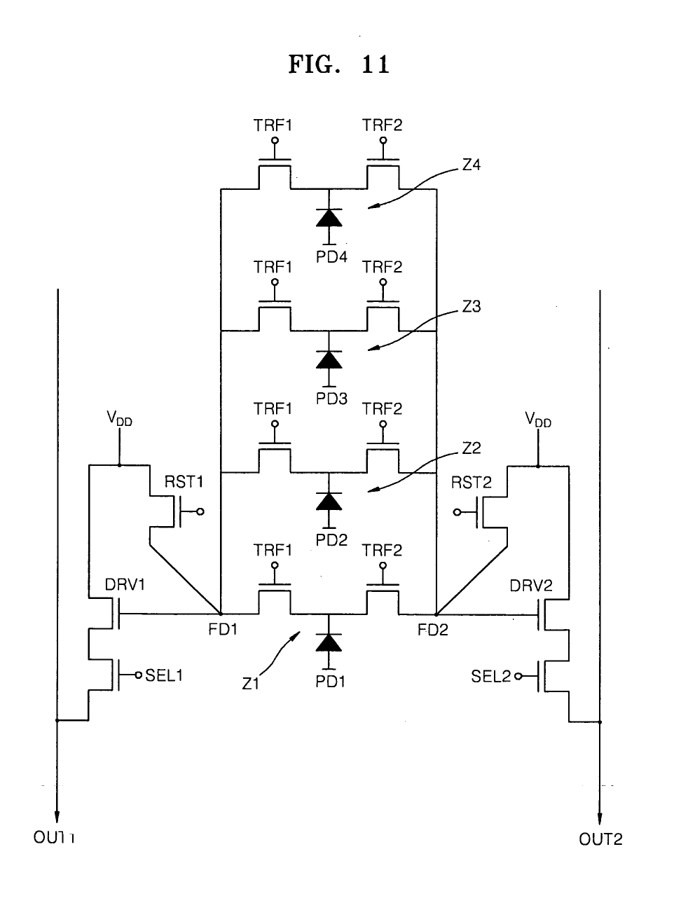

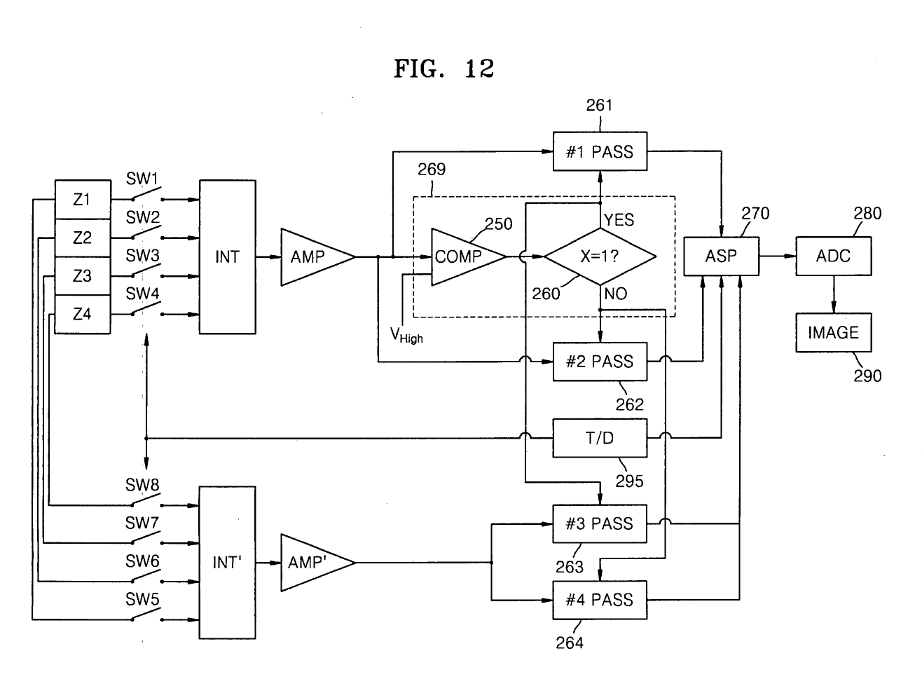

FIG. 11 is an equivalent circuit diagram of distance-measuring pixels Z1 through Z4, according to example embodiments, and FIG. 12 is a block diagram illustrating a three-dimensional image sensor including distance measuring pixels Z1-Z4 of FIG. 11.

Referring to FIGS. 11 and 12, each of the four distance-measuring pixels Z1 through Z4, which may be disposed adjacent to each other, may include one photodiode PD1 through PD4, and the first and second transfer transistors TRF1 and TRF2, to which charges from the corresponding photodiode PD1 through PD4 may be transferred with phase differences.

The first transfer transistors TRF1 of the distance-measuring pixels Z1 through Z4 may be connected to a first floating diffusion region FD1 in parallel, and the second transfer transistors TRF2 may be connected to a second floating diffusion region FD2 in parallel.

The adjacent distance-measuring pixels Z1 through Z4 may include a reset transistor RST1 connected to the first diffusion region FD1, a drive transistor DRV1 having a gate connected to the first floating diffusion region FD1, a select transistor SEL1, a reset transistor RST2 connected to the second floating diffusion region FD2, a drive transistor DRV2 having a gate connected to the floating diffusion region FD2, and a select transistor SEL2.

Meanwhile, photo gates (not shown) may be further disposed between the photodiodes PD1 through PD4 and the first and second transfer transistors TRF1 and TRF2.

In comparison to the structure of the color pixels shown in FIG. 9, the four adjacent distance-measuring pixels Z1 through Z4 may further include switching units SW5 through SW8, an integrator INT′ connected to the switching units SW5 through SW8, and an amplifier AMP′ to which a signal from the integrator INT′ may be transmitted. A signal from the integrator INT′ may be transmitted to a third pass gate 263 and a fourth pass gate 264, and the signals from the third and fourth pass gates 263 and 264 may be transmitted to the analog signal processor 270, the analog digital converter 280, and the image signal processor 290.

The integrator INT or INT′ may be used to measure intensity of illuminance of an object. The illuminance may be measured by using a signal from the integrator INT in FIG. 12, for convenience. Based on the measured illuminance, it may determined whether to integrate signals of the distance-measuring pixels Z1 through Z4 into one signal or to separately use the signals of the distance-measuring pixels Z1 through Z4.

The switching units SW1 through SW4 of FIG. 12 may respectively be the first transfer transistors TRF1 of the distance measuring pixels Z1 through Z4, and the switching units SW5 through SW8 may respectively be the second transfer transistors TRF2 of the distance-measuring pixels Z1 through Z4. Alternatively, the switching units SW1 through SW8 may be switches (not shown) respectively formed between the first and second transfer transistors TRF1 and TRF2, and the first and second floating diffusion regions FD1 and FD2.

The switching units SW1 through SW4 may be simultaneously turned on and the switching units SW5 through SW8 may be simultaneously turned on in a phase difference to the switching units SW1 through SW4, so as to integrate signals from the distance-measuring pixels Z1 through Z4. Additionally, the switching units SW1 through SW4 may be sequentially turned on, and corresponding switching units SW5 through SW8 may be sequentially turned on in a phase difference to the corresponding switching units SW1 through SW4 by using the time divider 295, so as to separately obtain the signals from the distance-measuring pixels Z1 through Z4. The time divider 295 may transmit a signal, which may include information about which switching unit is turned on, to the analog signal processor 270.

The amplifiers AMP and AMP′ of FIG. 12 may be constituted of the drive transistors DRV1 and DRV2, and the select transistors SEL1 and SEL2 of a corresponding pixel.

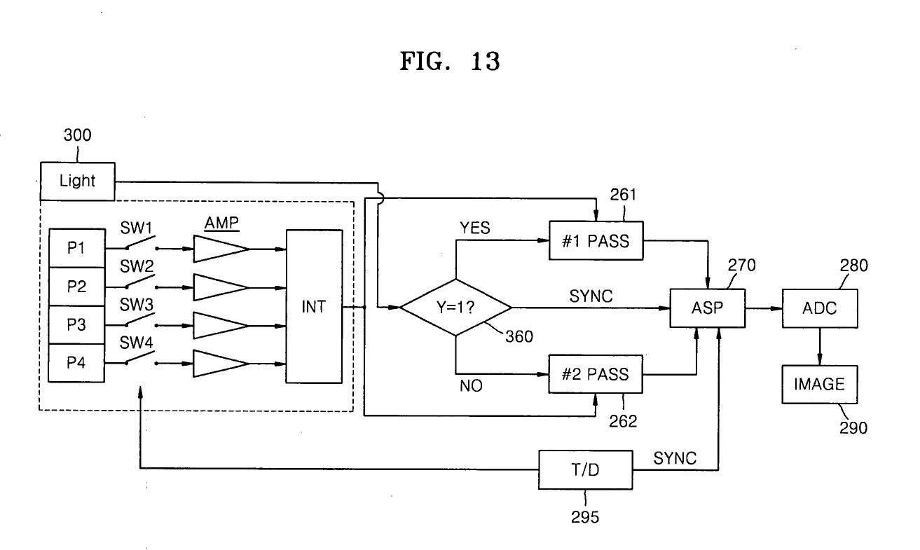

FIG. 13 is a block diagram illustrating a three-dimensional image sensor, according to another example embodiment.

Referring to FIG. 13, compared to the three-dimensional image sensor of FIG. 5, the three-dimensional image sensor depicted in FIG. 13 may further include an illuminance meter 300 for determining intensity of illuminance of an object and the time divider 295. The illuminance meter 300 may irradiate light having an infrared wavelength on an object, receive reflected light having an infrared wavelength from the object, and transmit an electric signal corresponding to the received light to a determiner 360. When it is determined that a value of the electric signal is equal to or less than a predetermined value, the determiner 360 may open the first pass gate 261, and when it is determined that the value of the electrical signal is above the predetermined value, the determiner 360 may open the second pass gate 262.

When the first pass gate is opened, the time divider 295 may turn on all of the switching units SW1 through SW4, and thus an analog signal integrated in the integrator INT may be transmitted to the first pass gate 261, and then the analog signal may be transmitted to the analog signal processor 270.

When the second pass gate 262 is opened, the time divider 295 may sequentially opens close the switching units SW1 through SW4 so as to transmit electric signals from the color pixels P1 through P4 to the integrator INT. Accordingly, the electric signals are sequentially transmitted to the analog signal processor 270. The time divider 295 may transmit a synchronization signal to the analog signal processor 270. The synchronization signal may include information about the color pixel from which the signal is transmitted to the analog signal processor 270.

The signal transmitted to the analog signal processor 270 may be converted to a digital signal in the analog-to-digital converter 280, and then transmitted to the image signal processor 290.

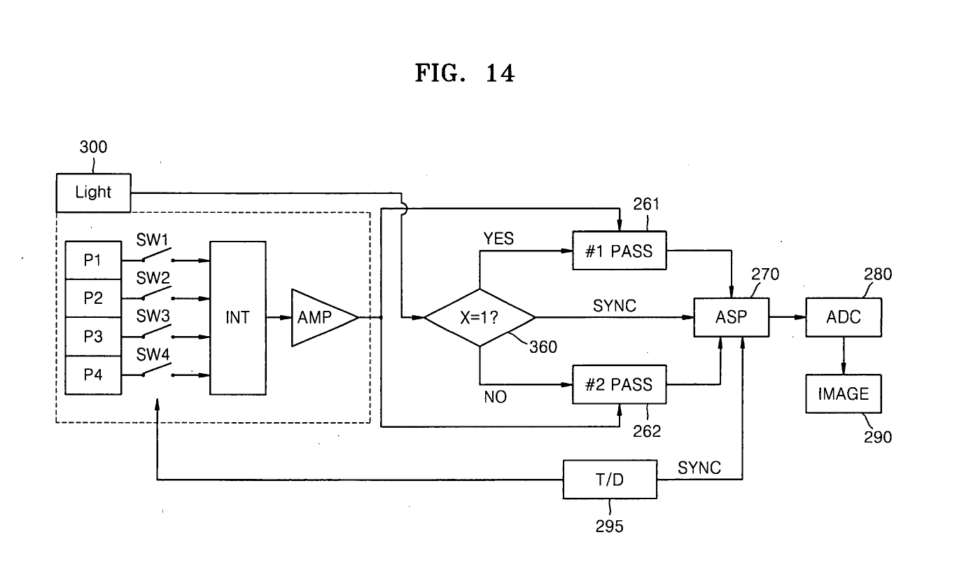

FIG. 14 is a block diagram illustrating a three-dimensional image sensor, according to another example embodiment.

Referring to FIG. 14, the three-dimensional image sensor according to the current embodiment may include the illuminance meter 300 as means for determining intensity of light from an object, compared to the three-dimensional image sensor of FIG. 9. The illuminance meter 300 may irradiate light having an infrared wavelength on an object, receive reflected light having an infrared wavelength from the object, and transmit an electric signal corresponding to the received light to the determiner 360. When it is determined that a value of the electric signal is equal to or below a predetermined value, the determiner 360 may open the first pass gate 261, and when it is determined that the value is above the selected value, the determiner 360 may open the second pass gate 262.

When the first pass gate 261 is opened, the time divider 295 may turns on all of the switching units SW1 through SW4, and thus an analog signal integrated in the integrator INT may be transmitted to the first pass gate 261, and then to the analog signal processor 270.

When the second pass gate 262 is opened, the time divider 295 may sequentially open and close the switching units SW1 through SW4, and thus the electric signals from the color pixels P1 through P4 may be sequentially transmitted to the integrator INT. Accordingly, the electric signals may be sequentially transmitted to the analog signal processor 270.

A signal transmitted to the analog signal processor 270 may be converted to a digital signal in the analog-to-digital converter 280, and then transmitted to the image signal processor 290.

The illuminance meter 300 in FIGS. 13 and 14 may be adapted to the three-dimensional image sensor in FIGS. 8 and 12, and details thereof are omitted.

FIG. 15 is a plan view schematically illustrating a pixel array 400 of a three-dimensional image sensor, according to another example embodiment.

Referring to FIG. 15, the pixel array 400 of the three-dimensional image sensor may include a color pixel pattern 412 and a distance measuring pixel pattern 414. The color pixel pattern 412 and the distance-measuring pixel pattern 414 may be arranged in an array form. Referring to FIG. 15, a plurality of, for example, 3, color pixel patterns 412 and one distance-measuring pixel 414 may be correspondingly arranged, but example embodiments are not limited thereto.

In FIG. 15, the color pixel pattern 412 Is illustrated as including a red pixel R, a green pixel G, and a blue pixel B, but example embodiments are not limited thereto. For example, the color pixel pattern 412 may include at least two of the red pixel R, the green pixel G, the blue pixel B, a magenta pixel Mg, a cyan pixel Cy, a yellow pixel Y, and a white pixel W.

The distance-measuring pixel pattern 414 may include a plurality of distance-measuring pixels, for example, 4 distance-measuring pixels Z1 through Z4. The red pixel R, the green pixel G, the blue pixel B, and each of the distance-measuring pixels Z1 through Z4 may have substantially the same size.

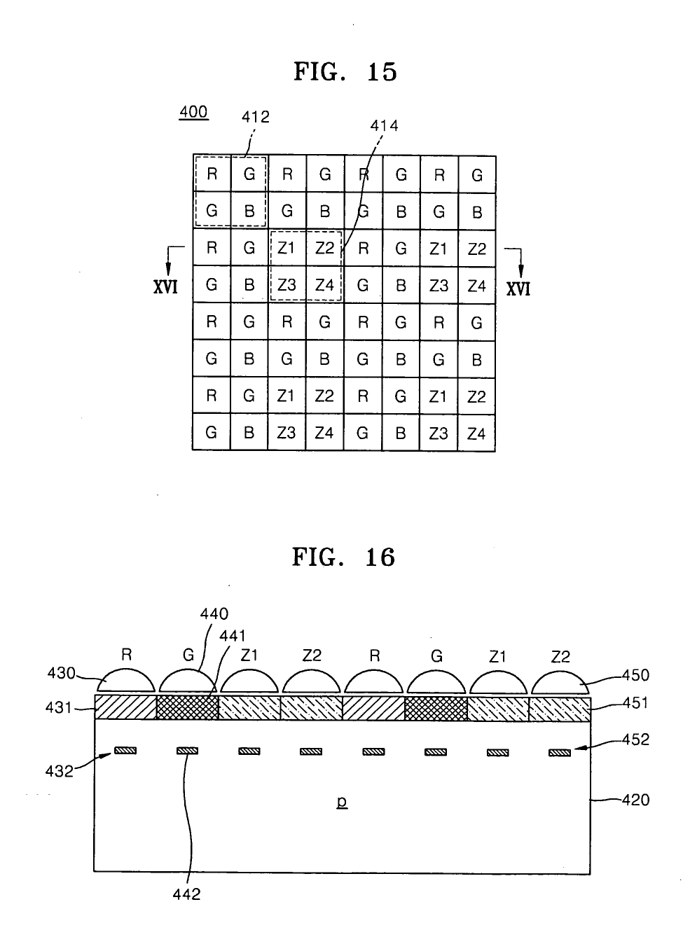

FIG. 16 is a cross-sectional view taken along line XVI-XVI of FIG. 15. Referring to FIG. 16, the red pixel R, the green pixel G, and the distance-measuring pixels Z1 and Z2 may be formed on a substrate 420, for example, a p-type silicon substrate. The red pixel R may include a micro lens 430, a red color filter 431, and a photoelectric conversion device 432. The photoelectric conversion device 432 may be an n-type region, and may form a p-n junction photodiode with the p-type substrate 420.

The green pixel G may include a micro lens 440, a green color filter 441, and a photoelectric conversion device 442. The photoelectric conversion device 442 may be an n-type region, and may form a p-n junction photodiode with the p-type substrate 420.

Each of the distance-measuring pixels Z1 and Z2 may include a micro lens 450, an infrared filter 451, and a photoelectric conversion device 452. The photoelectric conversion device 452 may be an n-type region, and may form a p-n junction photodiode with the p-type substrate 420.

The blue pixel B has the same structure as the green and red pixels G, and R, and details thereof are omitted.

The photoelectric conversion devices 432, 442, and 452 may substantially have the same depth from the surface of the substrate 420. Additionally, the micro lenses 430, 440, and 450 may have substantially the same size.

Accordingly, the photoelectric conversion devices 432, 442, and 452 are formed at the same depth from the substrate 420, and the micro lenses 430, 440, and 450 having the same size are formed via etching by using a conventional semiconductor process, and thus an image sensor including the pixel array 400 according to example embodiments may be easily manufactured.

When the illuminance is low, one pixel data is acquired by detecting sum of light irradiated on a region of four pixels Z1 through Z4 so as to use as each pixel data of the four pixels Z1 through Z4, and thus distance measuring sensitivity of the image sensor including the pixel array 400 may be improved. Additionally, when the illuminance is high, signals from the distance-measuring pixels Z1 through Z4 are separately used, and thus distance measuring resolution may be improved. Moreover, since each color pixel may be independently disposed, color image resolution may be improved.

The distance-measuring pixel pattern 414 may have the structure illustrated in FIGS. 7 and 8, or FIGS. 11 and 12, and details thereof are omitted.

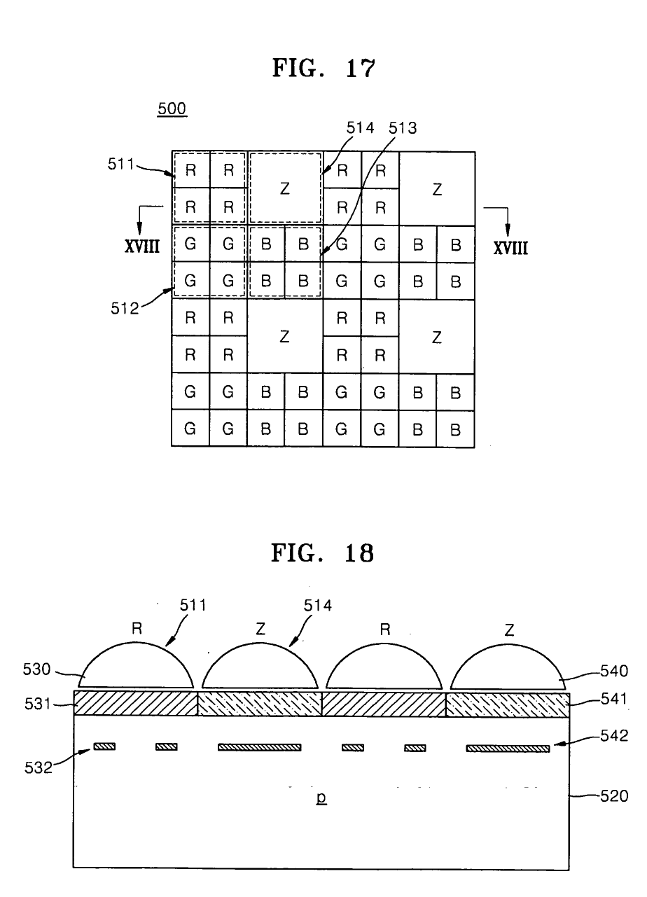

FIG. 17 is a plan view schematically illustrating a pixel array 500 of a three-dimensional image sensor, according to example embodiments.

Referring to FIG. 17, the pixel array 500 of the three-dimensional image sensor may include a color pixel pattern including a red pixel pattern 511, a green pixel pattern 512, and a blue pixel pattern 513, and a distance-measuring pixel pattern 514. Each of the red pixel, green pixel, blue pixel, distance-measuring pixel patterns 511, 512, 513, and 514 may substantially have the same size.

The red pixel pattern 511, the green pixel pattern 512, and the blue pixel pattern 513 are illustrated as including 4 red pixels R, 4 green pixels G, and 4 blue pixels B, respectively. In FIG. 17, each color pixel pattern includes 4 color pixels, but example embodiments are not limited thereto. For example, each color pixel pattern may include 2 or 3 color pixels.

In FIG. 17, the pixel array 500 is illustrated as including a color pixel pattern that includes the red pixel R, the green pixel G, and the blue pixel B, but example embodiments not limited thereto. For example, the color pixel pattern may include three pixels among the red pixel R, the green pixel G, the blue pixel, a magenta pixel Mg, a cyan pixel Cy, a yellow pixel Y, and a white pixel W.

The distance-measuring pixel pattern 514 may be formed of one distance-measuring pixel Z having a larger size considering low infrared light sensitivity.

FIG. 18 is a cross-sectional view taken along line XVIII-XVIII of FIG. 17. Referring to FIG. 18, the red pixel pattern 511 and the distance-measuring pixel pattern 514 may be formed on a substrate 520, for example a p-type silicon substrate. The red pixel pattern 511 may include corresponding red filters 531, and a micro lens 530, and four photoelectric conversion devices 532, each of which may correspond to the red pixels R. The green pixel pattern 512 and the blue pixel pattern 513 may have the same structure as the red pixel pattern 511, and details thereof are omitted.

The distance-measuring pixel pattern 514 may include a micro lens 540, an infrared filter 541, and a photoelectric conversion device 542.

The photoelectric conversion devices 532 and 542 may have substantially the same depth from the surface of the substrate 520. Additionally, the micro lenses 530 and 540 may have substantially the same size.

Accordingly, the photoelectric conversion devices may be formed at the same depth from the substrate 520, and the micro lenses, which may have the same size, may be formed via etching by using a conventional semiconductor process. Thus the three-dimensional image sensor including the pixel array 500 according to the current example embodiment may be easily manufactured.

When the illuminance is low, one pixel data may be acquired by detecting a sum of light irradiated on a region of four color pixels in each of the color pixel patterns 511, 512, and 513 so as to use as each pixel data in each of the color pixel patterns 511, 512, and 513. Thus color measuring sensitivity of the pixel array 500 may be improved. Additionally, when the illuminance is high, signals from each color pixel in each color pixel patterns 511, 512, and 513 may be separately used, and thus color measuring resolution may be improved.

Pixels of the color pixel patterns 511, 512, and 513 may have the structure illustrated in FIGS. 5 and 6, or FIG. 9 and 10, and details thereof are omitted.

FIG. 19 is a plan view schematically illustrating a pixel array 600 of a three-dimensional image sensor, according to example embodiments.

Referring to FIG. 19, the pixel array 600 may include a color pixel pattern 611 and a distance-measuring pixel pattern 614. The color pixel 611 and the distance-measuring pixel 614 may be arranged in an array form. In FIG. 19, a plurality of, for example, 3 color pixel patterns 611 may be disposed correspondingly to one distance-measuring pixel pattern 614, but are not limited thereto.

In FIG. 19, the color pixel pattern 611 is illustrated as including a red pixel R, a green pixel G, and a blue pixel B, but example embodiments are not limited thereto. For example, the color pixel pattern 611 may include at least 2 pixels among the red pixel R, the green pixel G, the blue pixel B, a magenta pixel Mg, a cyan pixel Cy, a yellow pixel Y, and a white pixel W.

The distance-measuring pixel pattern 614 may include one distance-measuring pixel Z which may have a substantially same size as the color pixel pattern 611. Generally, the distance-measuring pixel Z may have a larger size than a color pixel considering low infrared light sensitivity.

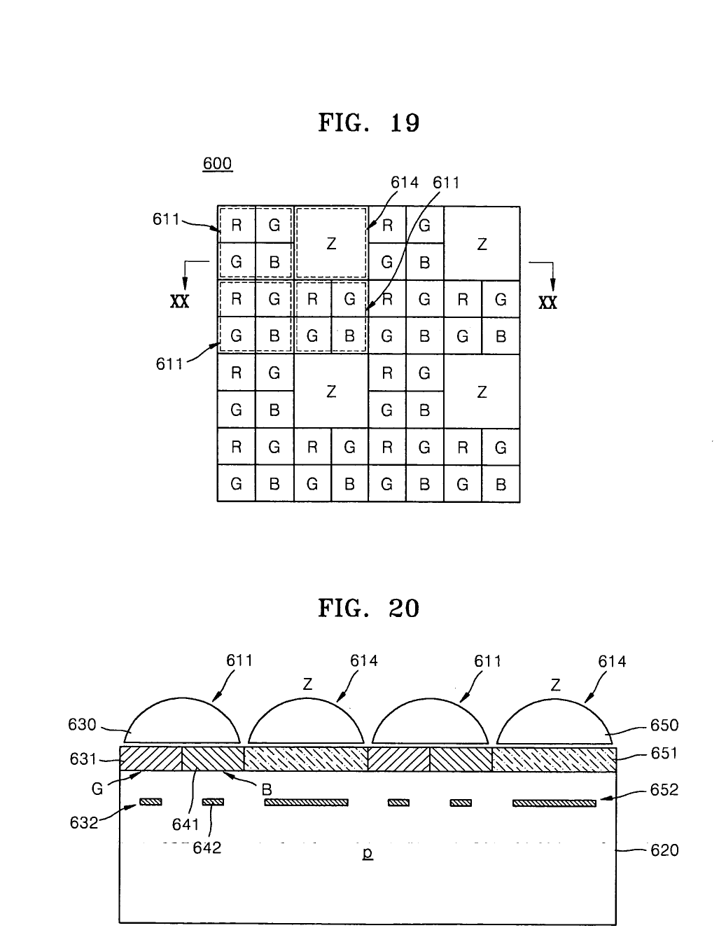

FIG. 20 is a cross-sectional view taken along line XX-XX of FIG. 19. Referring to FIG. 20, the color pixel pattern 611 and the distance-measuring pixel pattern 614 may be arranged on a substrate 620, for example a p-type silicon substrate. Micro lenses 630 and 650 may be arranged in the color pixel pattern 611 and the distance-measuring pixel pattern 614, respectively. The micro lenses 630 and 650 may have substantially the same size.

A green pixel G and a blue pixel B of the color pixel pattern 611 are illustrated in FIG. 20, and the structures of the other green pixel G and the red pixel R of color pixel 611 are not shown in FIG. 20. The structures of the other green pixel G and the red pixel R may be substantially same as the structures of the green pixel G and the blue pixel B, and details thereof are omitted.

Two green filters 631, one red filter (not shown), and one blue filter 641 may be disposed below the micro lens 630, and photoelectric conversion devices may be disposed below corresponding filters.

One distance-measuring filter 651 may be disposed below the micro lens 650, and a photoelectric conversion device 652 may be disposed below the distance-measuring filter 651.

The photoelectric conversion devices 632, 642, and 652 may have substantially the same depth from the surface of the substrate 620. Additionally, the micro lenses 630 and 650 may have substantially the same size.

Accordingly, the three-dimensional image sensor 600 of the current embodiment may be easily manufactured since the photoelectric conversion devices may be formed at the same depth from the substrate 620, and the micro lenses, which may have the same size, may be formed via etching by using a conventional semiconductor process.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A pixel array of a three-dimensional image sensor comprising:
a plurality of unit pixel patterns, each unit pixel pattern comprising one or more color pixels and a distance-measuring pixel which are arranged in an array form, wherein the plurality of the unit pixel patterns are arranged in such a way that a group of the distance-measuring pixels are disposed adjacent to each other.

2. The pixel array of claim 1, wherein the group of the distance-measuring pixels disposed adjacent to each other is four distance-measuring pixels, wherein the four distance-measuring pixels are arranged in a square form.

3. The pixel array of claim 1, wherein the one or more color pixels include at least two pixels selected from the group consisting of a red pixel, a green pixel, a blue pixel, a magenta pixel, a cyan pixel, a yellow pixel, and a white pixel.

4. The pixel array of claim 1, wherein each of the one or more color pixels and the distance-measuring pixel have substantially same size.

5. A pixel array of a three-dimensional image sensor comprising:
a first color pixel pattern comprising N adjacent first color pixels;
a second color pixel pattern comprising N adjacent second color pixels;
a third color pixel pattern comprising N adjacent third color pixels; and
a distance-measuring pixel pattern,
wherein N is a natural number larger than 2.

6. The pixel array of claim 5, wherein the first through third color pixels are selected from the group consisting of a red pixel, a green pixel, a blue pixel, a magenta pixel, a cyan pixel, a yellow pixel, or a white pixel.

7. The pixel array of claim 5, wherein the distance-measuring pixel pattern comprises N adjacent distance-measuring pixels, wherein each of the first through third color pixels and the distance-measuring pixel substantially has same size.

8. The pixel array of claim 5, wherein the distance-measuring pixel has an N-times larger size than each of the first through third color pixels.

9. A pixel array of a three-dimensional image sensor comprising:
a color pixel pattern including a plurality of adjacent color pixels; and
a distance-measuring pixel pattern having substantially the same size as the color pixel pattern.

10. The pixel array of claim 9, wherein the distance-measuring pixel pattern includes a plurality of distance-measuring pixels.

11. The pixel array of claim 9, wherein the distance-measuring pixel pattern includes a distance-measuring pixel having the same size as the color pixel pattern.

12. The pixel array of claim 9, wherein the color pixel pattern includes at least two pixels selected from the group consisting of a red pixel, a green pixel, a blue pixel, a magenta pixel, a cyan pixel, a yellow pixel, and a white pixel.

13. A three-dimensional image sensor comprising:
the pixel array of claim 1; and
a plurality of micro lenses, each of which is formed correspondingly to each of the one or more color pixels and the distance-measuring pixels,
wherein the plurality of the micro lenses each have substantially same size.

14. The three-dimensional image sensor of claim 13, wherein the group of the distance-measuring pixels disposed adjacent to each other is four distance-measuring pixels, wherein the four distance-measuring pixels are arranged in a square form.

15. The three-dimensional image sensor of claim 13, wherein the one or more color pixels includes at least two pixels selected from the group consisting of a red pixel, a green pixel, a blue pixel, a magenta pixel, a cyan pixel, a yellow pixel, and a white pixel.

16. The three-dimensional image sensor of claim 13, wherein each of the one or more color pixels and the distance-measuring pixel have substantially same size.
